(19) United States
(12) Patent Application Publication
(10) Pub. No.: US 2011/0102976 A1
(43) Pub. Date: May 5, 2011

(54) Electronic device having a windable screen

(76) Inventor: Tonny Chen, Shengang Shiang (TW)

(21) Appl. No.: 12/588,974

(22) Filed: Nov. 4, 2009

(51) Int. Cl. H05K 5/00

(52) U.S. Cl. 361/679.01

(57) ABSTRACT

An electronic device having a windable screen includes a flexible screen, a first chassis and a second chassis. The flexible screen has a windable free portion at an upper side that has a first anchor structure and a fastening portion at a lower side to be fastened to the first chassis. The first chassis has a plane to flatly hold and anchor the fastening portion of the flexible screen. The second chassis has at least one operation interface and a second anchor structure which is incorporated with the first anchor structure to wind and anchor the flexible screen. Thus when the first and second chassis are folded together the flexible screen can be securely stretched and wound at the outer side of the electronic device to facilitate holding and storing without occupying a lot of space.

### BACKGROUND OF THE INVENTION

1. Field of the Invention

The present invention relates to an electronic device having a windable screen with a first chassis and a second chassis that are foldable to stretch a flexible screen to facilitate storing without occupying a lot of space.

2. Description of the Prior Art

Progress of wireless networks makes development of computers (such as personal computers, notebook computers, navigation systems and the like) increasingly focused on portability. As product size directly impacts portability, slim, thin and light have become the prevailing trend of product design. Hence the display screen is made smaller. The smaller display screen makes operation and reading more difficult. Therefore the size of product and screen often is one of key factors in product design. These days advance of display screen technology makes rollable screen (commonly called flexible screen possible. A large screen can be rolled like a barrel to reduce the storing size and make portability of products easier to materialize.

While the rollable screen provides benefit for storing, it has to be incorporated with an operating host when in use. Hence a holding means has to be provided to hold the rollable screen rolled in a barrel fashion. The operating host usually is formed in a flattened and rectangular structure to facilitate operation and data entry. The rolled screen is cylindrical and does not match the rectangular host. Moreover, the rollable screen usually cannot be folded like paper to mate the size of the operating host. As a result, portability of the rollable screen still leaves a lot to be desired.

### SUMMARY OF THE INVENTION

Therefore it is an object of the present invention to provide an electronic device with a windable screen to allow a portable computer and a flexible screen to be coupled in a smaller size to facilitate carrying. The flexible screen has a windable free portion at an upper side that has a first anchor structure and a fastening portion at a lower side to be fastened to a first chassis. The first chassis has a plane to flatly hold and anchor the fastening portion of the flexible screen. There is also a second chassis which has at least one operation interface and a second anchor structure to be incorporated with the first anchor structure to wind and anchor the flexible screen. By means of the construction set forth above, the first chassis and the second chassis can be folded together, and the flexible screen can be stretched and securely wound on an outer side of the electronic device to facilitate storing without occupying a lot of space.

In one aspect of the invention the width of the first chassis and the second chassis is greater than the width of the flexible screen.

In another aspect, the first chassis and the second chassis have respectively a flange at an inner side and an outer side to protect the flexible screen.

In yet another aspect the second anchor structure of the second chassis is held in a housing trough and includes an anchor head, a sliding rod and an elastic element.

In still another aspect the first anchor structure has at least one anchor hole.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of an embodiment of the invention.

FIG. 2 is a fragmentary sectional view of the invention in a folding condition.

FIG. 3 is a perspective view of the invention in folding condition-1.

FIG. 4 is a schematic view of the second anchor structure in an operating condition.

FIG. 5 is a perspective view of the invention in folding condition-2.

FIG. 6 is a perspective view of the invention in folding condition-3.

### DESCRIPTION OF THE PREFERRED EMBODIMENTS

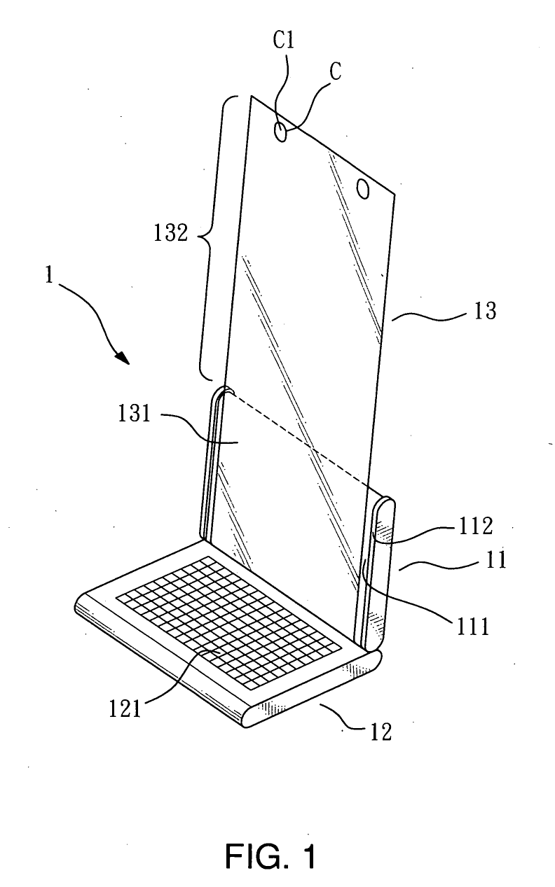

Please referring to FIG. 1, the electronic device 1 according to the invention includes a flexible screen 13, a first chassis 11 and a second chassis 12.

The flexible screen 13 has a windable free portion 132 at an upper side that has a first anchor structure C and a fastening portion 131 at a lower side to be fastened to the first chassis 11.

The first chassis 11 has a plane 111 to flatly hold and anchor the fastening portion 131 of the flexible screen 13 (with the plane 111 located at an inner side or outer side of the first chassis 11).

The second chassis 12 has at least one operation interface 121 and a second anchor structure B (referring to IG. 3) to be incorporated with the first anchor structure C to wind and anchor the flexible screen 13.

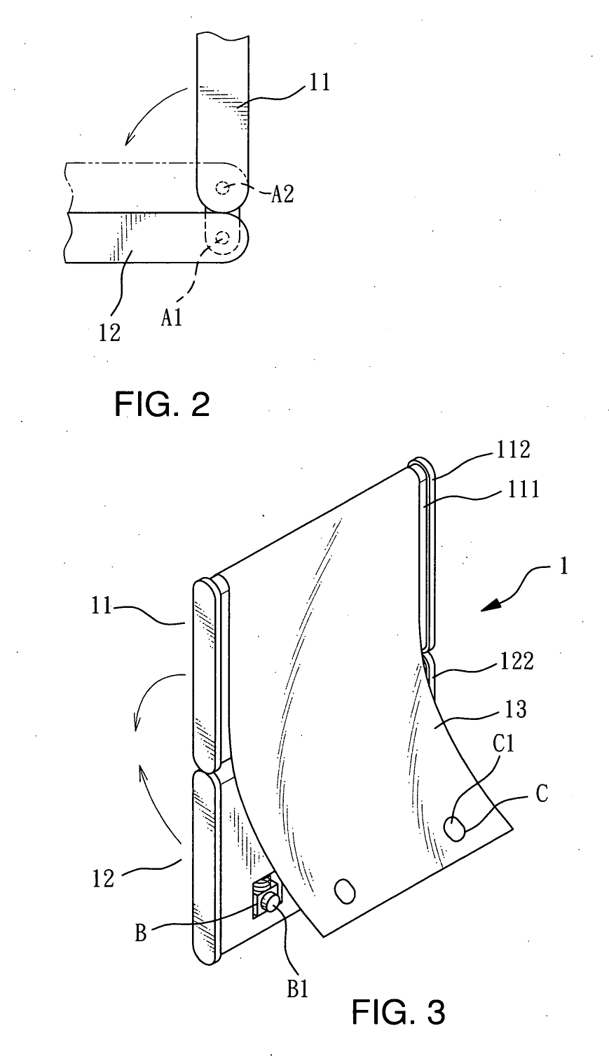

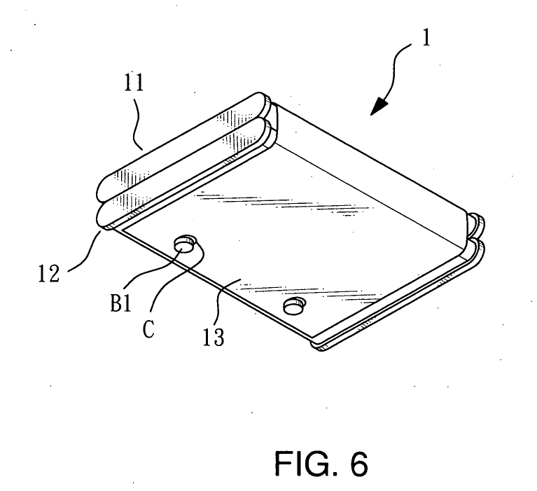

By means of the structure set forth above, when the invention is going to be folded (referring to FIGS. 2 through 5), the first chassis 11 and the second chassis 12 are turned respectively about a first axis A1 and a second axis A2 towards each other for folding, and the free portion 132 of the flexible screen 13 can be moved to wind around the outer side of the first and second chassis 11 and 12, and anchored through the first and second anchor structures C and B (referring to FIGS. 3 through 6). Thus the flexible screen 13 can wrap the electronic device 1 at the outer side to be positioned and anchored temporarily in the folding condition.

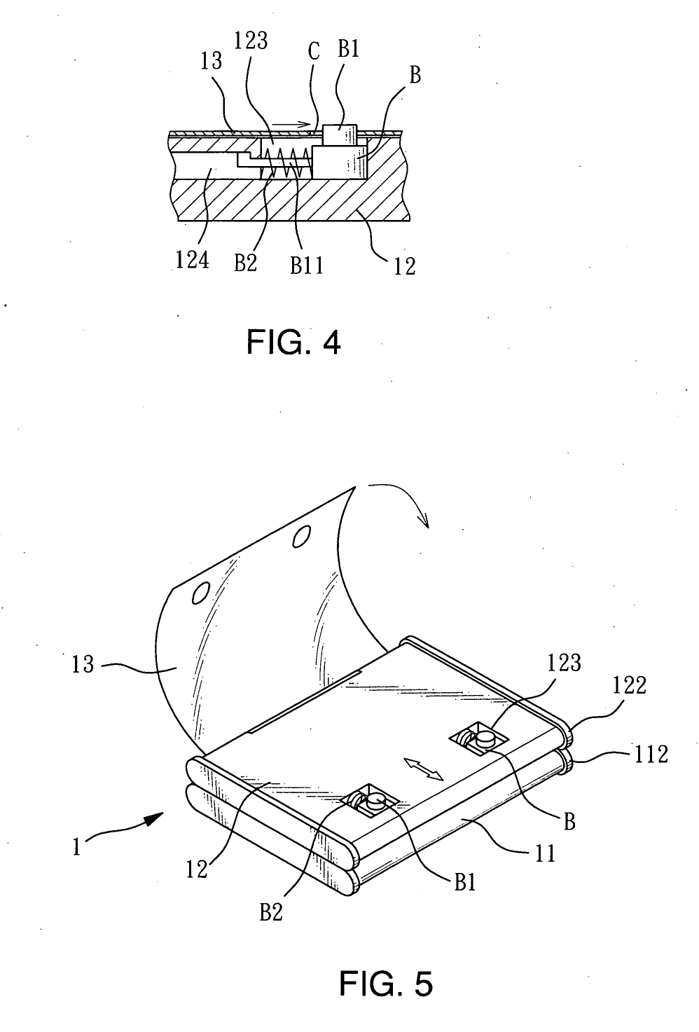

In order to make winding of the flexible screen 13 more secured in the folding condition, the second anchor structure B must have a desired elasticity and extendibility. To achieve this purpose the second anchor structure B includes an anchor head B1, a sliding rod B11 and an elastic element B2 (referring to FIG. 4) that are located in a housing trough 124 formed on the second chassis 12. The anchor head B1 is extended outside an opening 123 formed on the second chassis 12. The first anchor structure C has an anchor hole C1 engaging with the anchor head B1.The elastic element B2 has an elastic force to stretch the flexible screen 13 through the anchor head B1 to form a secure winding at the outer side of the electronic device 1.

In order to protect the flexible screen 13, the first and second chassis 11 and 12 are formed with a width greater than the width of the flexible screen 13. The first and second chassis 11 and 12 also have respectively a flange at an inner side and outer side.

As a conclusion, the invention in addition to making holding of the flexible screen easier, also can greatly reduce the size of the device. It provides a significant improvement for the existing products.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

I claim:

1. An electronic device having a windable screen comprising a flexible screen, a first chassis and a second chassis, wherein:
the flexible screen has a windable free portion at an upper side that has a first anchor structure and a fastening portion at a lower side to be fastened to the first chassis;
the first chassis has a plane to flatly hold and anchor the fastening portion of the flexible screen; and
the second chassis has at least one operation interface and a second anchor structure which is incorporated with the first anchor structure to wind and anchor the flexible screen;
wherein the first chassis and the second chassis are foldable together and the flexible screen is stretchable and windable at an outer side of the electronic device to facilitate holding and storing.

2. The electronic device of claim 1, wherein the first anchor structure has at least two anchor holes.

3. The electronic device of claim 1, wherein the second anchor structure includes an anchor head, a sliding rod and an elastic element.

4. The electronic device of claim 1, wherein the first chassis and the second chassis are formed at a width greater than the width of the flexible screen.

5. The electronic device of claim 1, wherein the first chassis has a first flange formed at an outer side thereof.

6. The electronic device of claim 1, wherein the first chassis has a first flange formed at an inner side thereof.

7. The electronic device of claim 1, wherein the second chassis has a second flange formed at an inner side thereof.

8. The electronic device of claim 1, wherein the second chassis has a second flange formed at an outer side thereof.
